(19) United States
(12) Patent Application Publication
(10) Pub. No.: US 2020/0166555 A1
(43) Pub. Date: May 28, 2020

(54) RF ENERGY METER

(71) Applicant: Drayson Technologies (Europe) Limited, London (GB)

(72) Inventors: Manuel Pinuela RANGEL, London (GB); Bruno Roberto FRANCISCATTO, London (GB); Alessandro REVELANT, London (GB); Alessandro VINCO, London (GB); Lewis Freeth HARPHAM, London (GB); Brian KREJCAREK, London (GB)

(21) Appl. No.: 16/076,728

(22) PCT Filed: Feb. 8, 2017
(86) PCT No.: PCT/GB2017/050320

§ 371 Date: Aug. 9, 2018

(30) Foreign Application Priority Data
Feb. 9, 2016 (GB) 1602357.4

(51) Int. Cl. G01R 29/08

(52) U.S. Cl. CPC G01R 29/0885; G01R 29/0871

(57) ABSTRACT

The present invention provides an apparatus comprising an RF energy harvester and an RF energy meter. The RF energy harvester comprises an antenna, a rectifier, an energy storage module and light output module. The antenna is arranged to receive an RF signal. The rectifier is arranged to generate a DC voltage from the received RF signal. The energy storage module is arranged to store the DC voltage. The light output module is arranged to output light pulses using the stored energy. The RF energy meter comprises a light detection module, a control module and an output module. The light detection module is arranged to detect light pulses output by the light output module of the RF energy harvester. The control module is arranged to count the number of light pulses detected by the light detection module. The output module is arranged to provide an output indicative of an amount of energy harvested by the RF energy harvester based on the counted number of light pulses.

### TECHNICAL FIELD

The present invention relates generally to the field of energy harvesting and more specifically to an RF energy harvester and an RF energy meter to provide an output indicative of the amount of RF energy harvested by the RF energy harvester.

### BACKGROUND

The wireless transmission of power has attracted considerable interest, and can be classified into two broad categories: wireless energy transfer and wireless energy harvesting. The former is used for high RF power densities (normally to transfer power from dedicated RF sources over short distances) while the latter relates to the harvesting of the much lower RF power densities that are typically encountered in the urban environment (e.g. from WiFi and mobile phone networks). Wireless energy harvesting systems are generally designed to profit from such freely available RF transmissions by employing highly efficient RF-to-DC conversion to supply low-power devices.

Energy harvesting environments have ultra-low power densities, typically 1 μW/cm² or less, and the density often fluctuates with time. As a result, the amount of energy harvested by an energy harvesting device is very small and time-dependent. This is makes it very difficult to determine, in a reliable and accurate way, the amount of energy harvested.

The present invention aims to provide an RF energy meter which can provide an output indicative of the amount of RF energy harvested.

### SUMMARY

The present invention provides an apparatus comprising an RF energy harvester and an RF energy meter. The RF energy harvester comprises an antenna, a rectifier, an energy storage module and light output module. The antenna is arranged to receive an RF signal. The rectifier is arranged to generate a DC voltage from the received RF signal. The energy storage module is arranged to store the DC voltage. The light output module is arranged to output light pulses using the stored energy. The RF energy meter comprises a light detection module, a control module and an output module. The light detection module is arranged to detect the light pulses output by the light output module of the RF energy harvester. The control module is arranged to count the number of light pulses detected by the light detection module. The output module is arranged to provide an output indicative of an amount of energy harvested by the RF energy harvester based on the counted number of light pulses.

The present invention also provides an RF energy meter optically coupleable to an RF energy harvester, the RF energy harvester comprising an antenna, a rectifier, an energy storage module and a light output module, the antenna arranged to receive an RF signal, the rectifier arranged to generate a DC voltage from the received RF signal, the energy storage module arranged to store the DC voltage and the light output module arranged output light pulses using the stored energy. The RF energy meter comprises a light detection module, a control module and an output module. The light detection module is arranged to detect the light pulses output by the light output module of the RF energy harvester. The control module is arranged to count the number of light pulses detected by the light detection module. The output module is arranged to provide an output indicative of an amount of energy harvested by the RF energy harvester based on the counted number of light pulses.

### BRIEF DESCRIPTION OF THE DRAWINGS

Embodiments of the invention will now be described, by way of example only, with reference to the accompanying drawings, in which like reference numbers designate the same or corresponding parts, and in which:

FIG. 1 shows a schematic view of an RF energy meter optically coupled to an RF energy harvester according to an embodiment of the present invention.

FIG. 2 shows a graph of voltage versus time for the generation of light pulses from the RF energy harvester and detected by the RF energy meter according to an embodiment of the present invention.

### DETAILED DESCRIPTION OF EMBODIMENTS

### First Embodiment

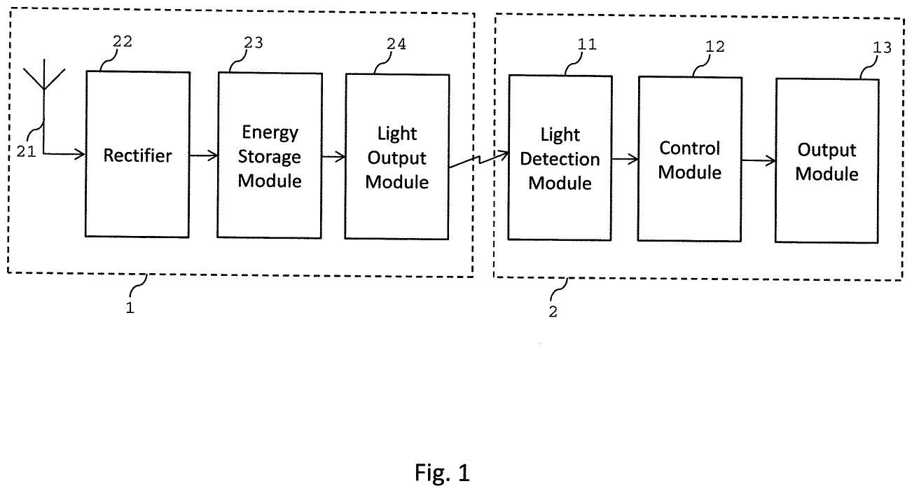

A first embodiment of the present invention will be described with reference to FIG. 1, which schematically shows the components of an RF energy harvester 1 and an RF energy meter 2.

The RF energy harvester 1 comprises an antenna 21, a rectifier 22, an energy storage module 23 and a light output module 24.

The antenna 21 is arranged to receive an RF signal. The antenna 21 may be optimised to receive any number of frequencies of RF signals, such as frequencies in the WiFi band of frequencies, typically 2.4 GHz-2.5 GHz, with the antenna 21 being optimal to receive signals at 2.45 GHz.

The rectifier 22 is arranged to generate a DC voltage from the received RF signal. Preferably, the rectifier 22 is configured to operate at the frequency received by the antenna 21 so as to minimise losses.

Energy harvested from RF signals is particularly weak. Typical energy harvesting environments have ultra-low power densities, roughly 1 μW/cm². To provide useful amounts of energy, the RF energy harvester 1 comprises an energy storage module 23 arranged to store and accumulate the DC voltage generated by the rectifier 22.

A number of methods of storage of electrical energy are possible. For example, batteries could be used to store the received RF energy. However, the present inventors chose to use capacitors such that the energy storage module 23 comprises a capacitor. They chose a capacitor because it has a small footprint.

When the energy stored in the energy storage module 23 is above a predetermined threshold, at least some of the energy is released to the light output module 24. The light output module 24 is arranged to output a light pulse using the energy. As a result of outputting energy to the light output module 24 the energy stored in the energy storage module 23 falls to a level below the predetermined threshold. The energy storage module 23 then charges up with further energy received from the rectifier 22 until the energy is again above the predetermined threshold, at which time it releases at least some of the energy to the light output module 24 for another light pulse. Accordingly, the process repeats in this way and the light output module 24 outputs a series of light pulses.

The light output module 22 may be implemented in a number of different ways. For example, lasers or filament bulbs may be employed. However, the present inventors chose LEDs because of their low power requirement and small footprint.

The energy harvester 2, as described above, may be configured as described in UK patent application GB 2517907 titled “RF Energy Harvester” filed on 9 Aug. 2013, but with the addition of the light output module 24. The energy harvester 2 may alternatively be configured as described in the GB application titled “Energy Harvesting Circuit Board” filed concurrently with the present application, but with the addition of the light output module 24. The antenna 21 may be configured as described in UK patent application GB 1513565.0 titled “Antenna” filed on 30 Jul. 2015. The antenna 21 may alternatively be configured as described in UK patent application GB 1515664.9 titled “Antenna” filed on 3 Sep. 2015. The rectifier 22 may be configured as described in UK patent application GB 1516280.3 titled “RF-to-DC converter” filed on 14 Sep. 2015. Alternatively, the rectifier 22 may be configured as described in UK patent application GB 1516282.9 titled “RF-to-DC converter” filed on 14 Sep. 2015. All of these documents are incorporated in their entirety herewith by cross-reference.

Turning now to the RF energy meter 2, the RF energy meter 2 comprises a light detection module 11, a control module 12 and an output module 13.

It will be appreciated that the RF energy harvester 1 and the RF energy meter 2 can be made and sold separately because they may be formed on separate circuit boards or the like.

The light detection module 11 is arranged to detect light pulses output by the light output module 24 of the RF energy harvester 1. Each light pulse corresponds to a predetermined amount of energy harvested by the RF energy harvester 1. In this way, the RF energy meter 2 is optically coupleable to the RF energy harvester 1.

The light detection module 11 could be implemented in a number of different ways. For example, a light dependent resistor, phototransistor or photomultiplier could be used. However, the present inventors have selected a photodiode for ease of use and high sensitivity.

To provide reliable and accurate outputs from the light detection module 11, the light output module 24 and the light detection module 11 are in close proximity and shielded so that no external light can leak onto the light detection module 11.

The RF energy meter 2 has its own battery power supply (not shown) so that it is electrically separated from the RF energy harvester 1, with no electrical energy from the RF energy harvester 1 being used to power the RF energy meter 2 or vice-versa.

The control module 12 is arranged to count the number of light pulses detected by the light detection module 11.

Turning now to the output module 13, this is arranged to provide an output indicative of the amount of energy harvested by the RF energy harvester 1 based on the counted number of light pulses.

The output module 13 may be implemented in a number of different ways to provide the output indicative of the amount of energy harvested by the RF energy harvester 1.

In the present embodiment the output module 13 is arranged to provide an output of the counted number of light pulses as the output indicative of the amount of energy harvested by the RF energy harvester 1.

In addition or instead, the output module 13 may be arranged to provide an output of the average of the counted number of light pulses per unit time as the output indicative of the amount of energy harvested by the RF energy harvester 1. In one example, this output is achieved by dividing the counted number of light pulses by the amount of time the control module 12 has been counting light pulses.

The control module 12 may determine the length of time in a number of ways. In one example, the control module 12 starts a time counter (e.g. counting seconds) when it starts counting light pulses so that, when the average light pulses per unit time is to be calculated, a length of time since the start of counting light pulses can be determined. Alternatively, or in addition to this, the control module 12 may utilise a real-time clock to keep track of the current time. The control module 12 may record the start time of light pulse counting and the current time and thereby determine the current duration of light pulse counting.

In a non-limiting example, the output module 13 may comprise a display. Any of the different display technologies may be utilised without compromising the effectiveness of the present embodiment. For example, an e-ink display, an LCD, an OLED or 7-segment display or any other type of display may be used.

Therefore, the above-described RF energy meter 2 is arranged to count the number of light pulses to provide, in real-time, an output indicative of the amount of energy harvested by the RF energy harvester 1.

### Second Embodiment

The second embodiment has the same components as the first embodiment but the functionality of the control module 12 and the output module 13 is different to that previously described.

According to the second embodiment, the control module 12 is arranged to count the number of light pulses detected by the light detection module 11 (as in the first embodiment). In addition, the control module 12 is further arranged to calculate an amount of energy harvested by the RF energy harvester 1 based on the counted number of light pulses. For example, the total amount of energy harvested by the RF energy harvester 1 may be calculated by multiplying the counted number of light pulses by the predetermined amount of energy that is released by the energy storage means 23 to cause each light pulse to be generated by the light output module 24.

Moreover, the control module 12 may, in addition or instead, calculate an average amount of power harvested by the RF energy harvester 1 by dividing the calculated amount of energy harvested by the length of time for which the RF energy meter 2 has been counting light pulses.

The control module 12 may determine the length of time in a number of ways. In one example, the control module 12 starts a time counter (e.g. counting seconds) when it starts counting light pulses so that, when the average power is to be calculated, a length of time since the start of counting light pulses can be determined. Alternatively, or in addition to this, the control module 12 may utilise a real-time clock to keep track of the current time. The control module 12 may record the start time of light pulse counting and the current time and thereby determine the current duration of light pulse counting.

The output module 13 is arranged to provide an output of the calculated amount of energy harvested by the RF energy harvester 1 as the output indicative of the amount of energy harvested by the RF energy harvester 1 (this being the calculated amount of energy harvested by the RF energy harvester 1 and/or the calculated average amount of power harvested by the RF energy harvester 1).

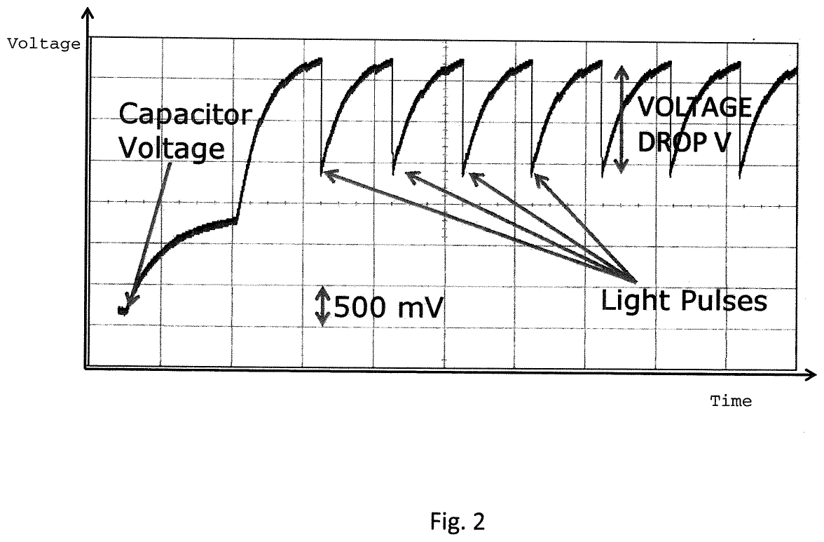

As explained previously, the calculation of the amount of energy harvested depends on a predetermined amount of energy released by the energy storage module 23 to cause each light pulse to be generated. FIG. 2 shows one method for predetermining this amount of energy. More particularly, FIG. 2 shows an oscilloscope plot of time on the x-axis versus voltage of the energy storage module 23 on the y-axis. An oscilloscope is only required for the initial calculation of the energy that each light pulse represents. Once this value has been found, an oscilloscope is no longer required and the apparatus can enter service and be used in any location without the further use of such bulky equipment.

In more detail, FIG. 2 shows the variation with time of the voltage measured across the energy storage module 21, in this case, comprising a capacitor.

As shown in FIG. 2, a series of LED pulses are shown together with the corresponding drop in capacitor voltage.

For each light pulse, a corresponding voltage drop of substantially 1.35 V was observed. The present inventors had selected a capacitor of size 100 μF as the energy storage module 23 in this embodiment. Using the equation

Energy=0.5×Capacitance×(Voltage Drop)²

each light pulse corresponds to a harvested energy amount of substantially 95 μJ.

Therefore, the RF meter 1 when calculating the total amount of energy harvested by the RF energy harvester 1, is arranged to multiply the counted number of light pulses by 95 μJ to find the total amount of energy harvested.

Embodiments may be useful for determining the amount of background energy available for harvesting at different locations and/or times in an easy to use manner.

The foregoing description of embodiments of the invention has been presented for the purpose of illustration and description. It is not intended to be exhaustive or to limit the invention to the precise form disclosed. Modifications and variations can be made without departing from the spirit and scope of the present invention.

1. An apparatus comprising:
an RF energy harvester comprising:
an antenna arranged to receive an RF signal;
a rectifier arranged to generate a DC voltage from the received RF signal;
an energy storage module arranged to store the DC voltage; and
a light output module arranged to output light pulses using the stored energy;
and
an RF energy meter comprising:
a light detection module arranged to detect the light pulses output by the light output module of the RF energy harvester;
a control module arranged to count the number of light pulses detected by the light detection module; and
an output module arranged to provide an output indicative of an amount of energy harvested by the RF energy harvester based on the counted number of light pulses.

2. The apparatus according to claim 1, wherein the energy storage module comprises a capacitor.

3. The apparatus according to any preceding claim, wherein the light output module comprises an LED.

4. The apparatus according to any preceding claim, wherein the output module is arranged to provide an output of the counted number of light pulses as the output indicative of the amount of energy harvested by the RF energy harvester.

5. The apparatus according to claim 4, wherein the output module is arranged to provide an output of the average of the counted number of light pulses per unit time as the output indicative of the amount of energy harvested by the RF energy harvester.

6. The apparatus according to any of claims 1 to 3, wherein:
the control module is arranged to calculate an amount of energy harvested by the RF energy harvester by multiplying the counted number of light pulses by a predetermined value which corresponds to the amount of energy that each light pulse represents; and
the output module is arranged to provide an output of the calculated amount of energy harvested as the output indicative of the amount of energy harvested by the RF energy harvester.

7. The apparatus according to claim 6, wherein:
the control module is arranged to calculate an average power harvested by the RF energy harvester by dividing the calculated amount of energy harvested by the amount of time the control module has been counting light pulses; and
the output module is arranged to provide an output indicative of the calculated average power harvested as the output indicative of the amount of energy harvested by the RF energy harvester.

8. The apparatus according to any preceding claim, wherein the light detection module comprises a photodiode.

9. The apparatus according to any preceding claim, wherein the output module comprises a display.

10. An RF energy meter optically coupleable to an RF energy harvester, the RF energy harvester comprising an antenna arranged to receive an RF signal, a rectifier arranged to generate a DC voltage from the received RF signal, an energy storage module arranged to store the DC voltage and a light output module arranged output light pulses using the stored energy, the RF energy meter comprising:
a light detection module arranged to detect the light pulses output by the light output module of the RF energy harvester;
a control module arranged to count the number of light pulses detected by the light detection module; and
an output module arranged to provide an output indicative of an amount of energy harvested by the RF energy harvester based on the counted number of light pulses.

11. The RF energy meter according to claim 10, wherein the output module is arranged to provide an output of the counted number of light pulses as the output indicative of the amount of energy harvested by the RF energy harvester.

12. The RF energy meter according to claim 11, wherein the output module is arranged to provide an output of the average of the counted number of light pulses per unit time as the output indicative of the amount of energy harvested by the RF energy harvester.

13. The RF energy meter according to claim 10, wherein:
the control module is arranged to calculate an amount of energy harvested by the RF energy harvester by multiplying the counted number of light pulses by a predetermined value which corresponds to the amount of energy that each light pulse represents; and
the output module is arranged to provide an output of the calculated amount of energy harvested as the output indicative of the amount of energy harvested by the RF energy harvester.

14. The RF energy meter according to claim 13, wherein:
the control module is arranged to calculate an average power harvested by the RF energy harvester by dividing the calculated amount of energy harvested by the amount of time the control module has been counting light pulses, and
the output module is arranged to provide an output indicative of the calculated average power harvested as the output indicative of the amount of energy harvested by the RF energy harvester.

15. The RF energy meter according to any of claims 10 to 14, wherein the light detection module comprises a photodiode.

16. The RF energy meter according to any of claim 10 to claim 15, wherein the output module comprises a display.
